(19) United States
(12) Patent Application Publication
(10) Pub. No.: US 2011/0011640 A1
(43) Pub. Date: Jan. 20, 2011

(54) INSULATING MEDIUM AND ITS USE IN HIGH VOLTAGE DEVICES

(75) Inventors: Ian Cotton, Wirral (GB); Ningyan Wang, Manchester (GB); Sarah Follmann, Newcastle Upon Tyne (GB); Jeffrey Robertson, Cheshire (GB)

Correspondence Address: IP Patent Docketing;K&L GATES LLP, 599 Lexington Avenue, 33rd Floor, New York, NY, 10022-6030, US

(73) Assignee: The University of Manchester, Manchester (GB)

(21) Appl. No.: 12/865,982

(22) PCT Filed: Feb. 18, 2009
(86) PCT No.: PCT/GB2009/000426

§ 371 Date: Aug. 3, 2010

(30) Foreign Application Priority Data
Feb. 21, 2008 (GB) 0803129.6

(51) Int. Cl. H01L 23/28; C08L 83/04; C08K 3/22; B05D 5/12

(52) U.S. Cl. 174/521; 524/1; 524/588; 524/413; 427/126.1

(57) ABSTRACT

An insulating composition for use in high voltage devices is formed from a soft dielectric casting compound, such as a silicone gel, comprising ferroelectric particles such as barium titanate dispersed within it. Low levels of particles, from 1% to 20% by volume of the insulating composition, are highly effective yet do not cause excessive thickening of the soft dielectric casting compound when it is in its liquid state. The insulating composition is particularly effective for coating, enrobing or encapsulating alternating high voltage devices such as power electronics devices in order to prevent electrical discharge.

The present invention relates to insulating compositions based, on soft casting compounds, such as silicone gels, for use in prevention of electrical discharge from high voltage devices. In particular, it relates to insulating compositions comprising ferroelectric particles for use in high voltage device modules such as power electronics modules.

In this specification, the term “high voltage device module” is used to describe a housing holding one or more high voltage devices and typically having the devices covered by an insulating composition. The increased desire to use power electronics devices at higher voltages in applications that demand reliable operation means that there is a need for highly effective insulating compositions to prevent electrical discharge from the locations in the power electronic module that are subject to high electric fields, to the surroundings, during operation. Power electronics modules are available which operate at voltages of 5 kV or higher and there is a drive to improve power density for modules by increasing voltages or by miniaturization. This leads to very high electrical field strengths (say 10 kV/mm) being present and it is likely that the insulating composition used to insulate the high voltage device from the surrounding module housing or casing will break down, leading to discharge or partial discharge of the voltage to the casing. Moreover, square-wave voltage switching is commonly employed in such power electronic modules, leading to a significant risk of partial discharge damage. Hence, improvements to the electrical insulation properties of insulating compositions used in such high voltage device modules are needed to allow further advances in miniaturization and higher electrical field gradients with microsecond or sub-microsecond rise times. Furthermore, improvements in manufacturing yield and product reliability are desirable. For instance, it would be highly desirable to be able to insert an insulating composition into the housing of a pre-fabricated power electronics module in liquid form, setting the composition once it is in place.

Such power electronics modules typically operate with local temperatures of 120° or more and a suitable insulating composition should be capable of maintaining its performance at 120° C. or higher.

A typical module may comprise a metallised ceramic substrate (such as aluminium nitride) soldered onto a base-plate acting as a heat sink. High voltage devices (such as insulated gate bipolar transistors (IGBT's)/diodes (usually silicon devices) or MOSFETs or JFETs) may be soldered to the ceramic substrate. Wires are then bonded to the individual device terminals to enable external connections to be made, and the whole assembly is then immersed in a soft casting compound, which is a dielectric insulating composition, in order to provide a hermetic seal against the environment as well as providing resistance to electrical breakdown along the surfaces of the substrate or between parts of the module subject to high electrical fields. Air alone is an inadequate dielectric for the high fields typically present. Soft dielectric insulating materials, such as silicone gels or cross-linked rubber compounds may be used as soft casting compounds for power electronics devices. Such compounds have an initial flowable state and a further gelled state in which they are no longer flowable. They have the advantage that they can be inserted into the module housing in the form of a free-flowing liquid by pouring, or as a more viscous liquid by injection, to ensure that good contact is made with all surfaces, and then can be subsequently cured (typically by heating in the presence of a catalyst) to provide a soft, gelled, dielectric solid viscoelastic material. Usually, the silicone compound is degassed prior to gelation (by placing the module housing under vacuum) in order to remove any air bubbles that could lead to electrical breakdown paths and partial discharge. Three dielectric systems can be defined within a power electronics device module: (i) the ceramic substrate, (ii) the soft casting compound and (iii) the interface between the ceramic and the soft casting compound. It is the latter interface that is often the weakest part in a power electronics module with regard to electrical breakdown.

WO 03/001594 discloses a high voltage module comprising a structural component fastened on a metal-ceramic substrate. The device further comprises a cast gel including weakly conductive particles, or particles having a high dielectric constant (compared to the gel) such as 8 in the gel, located on the outer edges of the substrate.

DE 199 17 477 discloses an insulating plastic or rubber for use as a high voltage cable insulator comprising particles of high dielectric constant, such as barium titanate, embedded therein. It makes no mention of soft casting compounds having a flowable and a gelled state, such as those useful for insulators in high voltage device modules.

It is one object of the present invention, amongst others, to provide an insulating composition for use in high voltage device modules which has greater resistance to electrical breakdown than prior art compositions, particularly for alternating electrical fields, but without significant reduction in the desirable characteristics of such prior art soft casting compositions such as silicone gels or cross-linked rubber compounds.

It has now been found that insulating compositions having a field dependent electrical permittivity can be formed through the inclusion of ferroelectric particles in a soft casting composition such as a silicone gel or cross-linked rubber compound. Without wishing to be bound by any theory, it seems that their functionality as electrical stress-reducing materials relies on enhanced polarisation mechanisms, through a process of spontaneous domain alignment occurring in the ferroelectric particles at high electric field strengths. It seems that these enhanced polarisation effects give the resulting composite insulating composition an enhanced permittivity at elevated electrical field strengths. It has been found that this enhanced permittivity does not require the particles to be in contact throughout the insulating composition. In other words, it is not necessary for the particles to be present at a level so high that the percolation threshold for the particles is exceeded such that continuous chains of particles in contact are formed. When the level of particles is so high that the percolation threshold level is exceeded, this can result in high viscosity and may make the filled casting composition difficult to pour or cast. The inclusion of ferroelectric particles in a soft casting composition does not permit the flow of current, and so the resulting composition remains electrically insulating.

However, as the stress relieving properties of the insulating composition seem to be driven through electrical field dependent polarisation/permittivity mechanisms, the effects are only realisable under alternating fields.

Hence, a first aspect of the invention provides an insulating composition for use in high voltage devices comprising a soft dielectric casting compound characterised in that the soft dielectric casting compound comprises ferroelectric particles dispersed therein.

By soft dielectric casting compound is meant a compound, which is suitable for casting into a device enclosure or housing. For the avoidance of doubt, the term as used herein refers to the compound after it has gelled or solidified, in other words after completion of gelation of the soft casting compound. This compound will be a liquid initially, allowing it to be inserted into the housing easily by injection or pouring or some other suitable means. The term casting means to use a liquid to take on the shape of a mould and then to set the liquid so that it retains that shape. Also, when as a liquid, prior to completion of solidification or gelation, the soft dielectric casting compound may flow, or be induced to flow, to contact all device parts accessible within the housing acting as a mould. As a free-flowing liquid it can also be degassed simply by application of a vacuum. In order to provide durability and orientability of the device containing the soft dielectric casting compound without risk of loss of electrical insulation, the compound then sets by conversion from a liquid into a soft solid by a gelation or solidification mechanism. This may be achieved by any suitable means such as chemical reaction induced by reactant addition or release, heat, catalysis, radiation or a mixture of all or any of these. The gelation reaction may commence prior to the placement of the compound into the housing, provided that the compound remains flowable enough to be poured or injected into the housing. Compounds which are soft rather than brittle or highly resilient are preferred as they are less likely to cause damage to the components of the device module through thermal expansion when the device is operated. They also provide improved adhesion to surfaces within the device module when subjected to thermally induced stress. By the term “completion of gelation” as used herein is meant that the compound is no longer flowable after completion of gelation.

A preferred soft dielectric casting compound is silicone gel. Such compounds are commercially available and well known in the field. Typical commercial material is available from ACC® Silicones Europe as Q Gel300 Series addition cure materials. These are 2-part materials, typically comprising a vinyl-ended silicone polymer which is mixed with a silicone hydride cross-linker. Reaction between the compounds is catalysed by platinum and is temperature sensitive (with curing being typically accelerated by heating above room temperature).

Following initial mixing of the two silicones and the catalyst at say 25° C., a free-flowing liquid is formed, typically with a viscosity of about 1000 mPa·s (at a shear rate of 1 sec⁻¹). The ferroelectric particles may be dispersed in the free flowing liquid, which is sufficiently viscous to hold them in a dispersed state prior to curing without excessive settling. The resulting composition may then be poured or injected into the housing of a device module and set by heating in an oven at a temperature according to the manufacturer's instructions.

Suitably, the insulating composition of the first aspect of the invention comprises from 1% to 20% by volume of ferroelectric particles, preferably from 5% to 18%, more preferably from 10% to 16%. Too low a level of particles does not provide sufficient electrical field stress relieving behaviour, whereas too high a level can lead to the soft casting compound being too solid-like when in its initial, uncured state, leading to difficulties in inserting the insulating compound into a device enclosure and poor flow characteristics such that the insulating compound may not flow to contact all surfaces of the device in the housing or enclosure. Excessively high levels of ferroelectric particles may also inhibit the curing reaction of the soft casting compound, particularly when a catalyst such as platinum is used for catalysing the curing reaction.

The ferroelectric particles are suitably dispersed within the soft dielectric compound. By this it is meant that the ferroelectric particles are relatively homogeneously distributed throughout the soft dielectric compound when it is in its final gelled state. In other words, when sampled using a 5 ml sample volume, the standard deviation in the volume level of ferroelectric particles will be less than 50% of the mean volume, preferably less than 30%, more preferably less than 10%. Prior to gelation, the particles will tend to settle out under gravity at a rate that will be determined by the particle size, the density difference between the particles and the casting compound, and the viscosity of the casting compound when in its liquid state prior to gelation. Soft casting compounds of various viscosities are commercially available, and the skilled person would have no difficulty in selecting a soft casting compound having a high enough viscosity to allow the ferroelectric particles to remain suspended in a dispersed state until gelation has occurred. If necessary, the soft casting compound may be partially gelled to increase its viscosity whilst the ferroelectric particles are being dispersed in it. However, the compound should still have a sufficiently low viscosity that it may be dosed into a housing enclosure of a device module whilst still holding the dispersed ferroelectric particles in suspension. Preferably, the soft casting compound commences gelation shortly after being filled into the housing enclosure of a device module and preferably degassed, such that the ferroelectric particles do not sediment out or stratify.

As explained above, a preferred soft casting compound is a silicone gel, particularly preferred are silicone gels which cure by an addition curing route, although silicone gels which cure by a condensation route may also be suitable. The former silicone gels have a cure mechanism that can be enhanced by heating, and so it is relatively easy for the completion of gelation to be delayed until after the ferroelectric particles have been dispersed in the uncured silicone gel.

Although the insulating compound of the invention may contain other ingredients such as fillers or pigments, preferably the insulating composition consists essentially of the soft casting compound and ferroelectric particles, meaning that any other ingredients are present at a total level of less than 3% by weight such that they do not interfere with the function of the invention.

Suitably, the ferroelectric particles have a weight mean particle diameter from 0.5 to 20 μm, preferably from 1 to 10 μm, more preferably from 1 to 5 μm. Typically, the particles have at least 50% by weight less than 10 μm, preferably less than 7 μm, more preferably less than 5 μm. Preferably, the particles have at least 95% by weight less than 10 μm, preferably less than 7 μm, more preferably less than 5 μm. This may be measured by particle size analysis by light scattering using an apparatus such as a Malvern Mastersizer™ model S, with a 300 RF lens (measurement range 0.05-3480 μm), Malvern Mastersizer software v 2.18 and a DIF 2012 dispersion unit. This instrument, made by Malvern Instruments, Malvern, Worcestershire, utilises Mie theory to calculate the particle size distribution. Mie theory predicts how light is scattered by spherical particles and takes into account the refractive index of the particles. A constant density for the ferroelectric particles is assumed for deriving the weight mean particle size from the data.

Larger particle sizes may result in settling out of the particles prior to curing of the soft casting compound such that the particles are not dispersed within the soft casting compound. This can lead to sedimentation or stratification. Also, larger particles can lead to uneven electrical flux distribution within the insulating composition. Large particles can also lead to higher, field-dependent electrical fluxes, leading to an increase in the electrical permittivity for the composition. Smaller particles, such as nano-particles, do not possess ferroelectric properties as the particle size may be too small for the required unit cell shape to be adopted. For instance, for barium titanate, the cell will be cubic rather than tetragonal leading to loss of the ferroelectric effect so that the particles become para-electric. Also, for particles less than 1 μm in diameter, defects on particle boundaries or disordered surface regions may reduce the particle permittivities, leading to a concomitant reduction in the permittivity of the overall insulating composition

Preferably, the ferroelectric particles comprise or consist essentially of barium titanate. (By “consist essentially” is meant that less than 3% of other impurities are present). Barium titanate is a particularly effective ferroelectric material. Surprisingly, although Barium Titanate is known to have a Curie point of about 120° C. as a pure material, the insulating compositions of the invention have been found to maintain their ferroelectric properties and resistance to discharge inception up to a device operating temperature of 140° C.

Suitably, the insulating composition of the first aspect of the invention is essentially free from gas bubbles, meaning it contains less than 3% by volume, preferably less than 1%, more preferably less than 0.1%. This may be measured by calculation from the known densities and levels of the other materials present in the insulating composition.

The thermal conductivity of the soft casting compositions of the invention higher is than that of unmodified soft casting compositions. This provides a further advantage in assisting in eliminating hot-spots located at or near interfaces between the soft casting composition and the encapsulated device.

All preferred features of the first aspect of the invention also apply to the second and third aspects of the invention as detailed below.

A second aspect of the invention provides high voltage device module comprising a high voltage device in a housing enclosure wherein the device is covered with an insulating composition according to the first aspect of the invention. Suitably, all surfaces of the device are coated with the insulating composition. Preferably, the housing enclosure is filled with the insulating composition.

A third aspect of the invention provides a method for preparing an insulating composition according to the first aspect of the invention comprising the steps of:

a) providing precursor components, at least one of which is in liquid form, which are blended to form a soft dielectric casting compound,
b) dispersing ferroelectric particles into one or more of the precursor components, prior to blending the precursor components, and/or into the soft dielectric casting compound following blending of the precursor components, prior to completion of gelation of the soft dielectric casting compound, to form the insulating composition,
whereby the ferroelectric particles are homogeneously dispersed through the resulting insulating composition. The method may include the further step of degassing the soft dielectric casting compound, with ferroelectric particles dispersed therein, prior to completion of its gelation.

For instance, when the soft casting compound is a silicone gel, comprising two liquid precursor Components, silicone A and silicone B, including a catalyst, the ferroelectric particles may be dispersed in either silicone A or in silicone B prior to mixing them together; or may be mixed into both silicone A and silicone B prior to their mixing together to form a curable composition. Another method is to mix together silicones A and B simultaneously with the addition of the ferroelectric particles. Alternatively, silicones A and B may be mixed to form a liquid, then the ferroelectric particles dispersed into the mix prior to completion of its gelation.

The method of the third aspect of the invention may comprise the further step of inserting the insulating composition into the housing enclosure of a high voltage device module prior to completion of gelation of the soft casting compound.

Hence, a fourth aspect of the invention provides a method for providing an insulating composition around a high voltage device in a housing enclosure comprising:

a) providing a high voltage device housed in a housing enclosure having an inlet aperture,
b) providing precursor components, at least one of which is in a liquid form, which are blended to form a soft casting compound,
c) dispersing ferroelectric particles into one or more of the precursor components, prior to blending the precursor components, and/or into the soft casting compound following blending of the precursor components, prior to completion of gelation of the soft dielectric casting compound,
d) inserting the soft dielectric casting compound, with ferroelectric particles dispersed therein, into the housing enclosure through the inlet port prior to completion of gelation of the filled soft casting compound, with ferroelectric particles dispersed therein, to form the insulating composition.

The method of the fourth aspect of the invention may comprise the step of degassing the soft dielectric casting compound, with ferroelectric particles dispersed therein, prior to completion of its gelation. This degassing step may be achieved prior to, or after, insertion of the soft casting compound, in its flowable state, into the housing enclosure.

The invention will now be described further by reference to the following examples:

### EXAMPLES

### Example 1

Ten substrate samples each having a “U”-shaped outer electrode and an inner electrode located inside the “U” were used to measure the onset of partial electrical discharge when surrounded by an unfilled silicone gel and when surrounded by the same silicone gel filled with 15% barium titanate particles by volume (corresponding to 52% by weight). The barium titanate particles had a particle size distribution with 95% by weight less than 5.0 μm and 50% by weight less than 1.7 μm. The measurement was carried out at room temperature, about 25° C.

Two wires were connected to the two electrodes on the substrate. The U-shaped electrode was connected to high voltage and the central electrode earthed. Once electrical connection was made, the substrate was placed in plastic housing and the housing filled with either unfilled or filled silicone gel. The silicone gel used was Q-gel™ 310 available from ACC® Silicones. This silicone gel is formed by mixing two components (A and B) in a 1:1 ratio by volume. Curing begins as soon as the components A and B are mixed and the rate of gelation depends upon temperature. The viscosities of the filled and unfilled gels were measured just after mixing the two precursors (A—vinyl terminated polymer & B—hydride cross-linker) of the commercial silicone gel. The barium titanate was added to part A of the gel before part B was added.

The viscosity of the resulting liquid composition, prior to curing, was found to be relatively unaffected by the presence of the barium titanate, such that the composition could still be easily inserted into a device housing.

All samples were degassed under vacuum for 1 hour then cured in an oven at 90° C. for 1 hour. The samples were then kept either in an environmental chamber at low humidity (RH=25%) or high humidity (RH=83%) for 56 days prior to measurement, with temperature cycling between 20° C. and 90° C. This is because power electronics modules are not usually hermetically sealed and so allowing the gel to absorb moisture should provide more relevant data.

A conventional partial discharge measurement circuit according to IEC 60270 was used to measure discharge inception voltage, breakdown voltage and partial discharge distribution using a sinusoidal alternating voltage at 50 Hz. Average values are shown in Table 1.

TABLE 1

| | 50 Hz Discharge | 50 Hz Breakdown |
|---|---|---|
| Unfilled Gel | 8.99 kV | 10.24 kV |
| Filled Gel | 11.64 kV | 14.44 kV |
| Percentage | 29.5% | 41% |
| Improvement | | |

### Example 2

The experiment of Example 1 was repeated with a 50 Hz square wave voltage (25 μs rise time). The results are shown in Table 2

TABLE 2

| | 50 Hz Discharge | 50 Hz Breakdown |
|---|---|---|
| Unfilled Gel | 6.04 kV | 9.70 kV |
| Filled Gel | 8.11 kV | 10.52 kV |
| Percentage | 34.3% | 8.5% |
| Improvement | | |

For square wave excitation, the data demonstrate a marked improvement in the discharge inception voltage for the filled gel compared to the unfilled gel.

### Example 3

Experiments were also carried out using commercial 3.3 kV power electronic modules in housings surrounded by either degassed unfilled gel or degassed filled gel. The filled gel had either 10% by volume of barium titanate or 15% by volume of barium titanate. The results for discharge inception are shown in table 3 and for breakdown in table 4.

TABLE 3

| | 0% (Unfilled) | 10% | 15% |
|---|---|---|---|
| Discharge Inception (kV) | 6.3 | 8.4 | 10.1 |
| Increase vs. unfilled | 0 | 33.3% | 60.3% |

TABLE 4

| | 0% (Unfilled) | 10% | 15% |
|---|---|---|---|
| Breakdown (kV) | 10.4 | 13.5 | 15.2 |
| Increase v. unfilled (%) | 0 | 29.9% | 46.2% |

It is clear that higher concentration results in better results in terms of discharge inception voltage.

### Example 4

The thermal conductivity of the gel containing 15% by volume of barium titanate (52% by weight) was measured and found to be 0.22 W/m° K whereas the thermal conductivity for the unfilled gel was 0.16 W/m° K. This provides a further advantage for the filled gel in that the higher thermal conductivity may assist with elimination of hot-spots located at or near gel/device interfaces.

It should be understood that while the use of words such as “preferable”, “preferably”, “preferred” or “more preferred” in the description suggest that a feature so described may be desirable, it may nevertheless not be necessary and embodiments lacking such a feature may be contemplated as within the scope of the invention as defined in the appended claims. In relation to the claims, it is intended that when words such as “a,” “an,” “at least one,” or “at least one portion” are used to preface a feature there is no intention to limit the claim to only one such feature unless specifically stated to the contrary in the claim. When the language “at least a portion” and/or “a portion” is used the item can include a portion and/or the entire item unless specifically stated to the contrary.

1. An insulating composition for use in high voltage device modules comprising a soft dielectric casting compound wherein the soft dielectric casting compound comprises ferroelectric particles dispersed therein.

2. The insulating composition of claim 1 wherein the insulating composition comprises from 1% to 20% by volume of ferroelectric particles.

3. The insulating composition of claim 1 wherein the soft dielectric casting compound is a silicone gel.

4. The insulating composition of claim 1 wherein the insulating composition consists essentially of the soft dielectric casting compound and ferroelectric particles.

5. The insulating composition of claim 1 wherein the ferroelectric particles have a weight mean particle diameter from 0.5 to 20 μm.

6. The insulating composition of claim 1 wherein the ferroelectric particles comprise or consist essentially of barium titanate.

7. The insulating composition of claim 1 which is essentially free from gas bubbles.

8. A high voltage device module comprising a high voltage device in a housing enclosure wherein the device is covered with the insulating composition of claim 1.

9. The high voltage device module of claim 8 wherein the housing enclosure is filled with the insulating composition.

10. A method for preparing the insulating composition of claim 1 comprising:
a) providing precursor components, at least one of which is in liquid form, which are blended to form a soft dielectric casting compound, and
b) dispersing ferroelectric particles into one or more of the precursor components, prior to blending the precursor components, and/or into the soft dielectric casting compound following blending of the precursor components, prior to completion of gelation of the soft dielectric casting compound, to form the insulating composition,
whereby the ferroelectric particles are homogeneously dispersed through the resulting insulating composition.

11. The method of claim 10 further comprising the step of degassing the soft dielectric casting compound, with ferroelectric particles dispersed therein, prior to completion of its gelation.

12. A method for providing an insulating composition around a high voltage device in a housing enclosure comprising:
a) providing a high voltage device housed in a housing enclosure having an inlet aperture,
b) providing precursor components, at least one of which is in a liquid form, which are blended to form a soft casting compound,
c) dispersing ferroelectric particles into one or more of the precursor components, prior to blending the precursor components, and/or into the soft casting compound following blending of the precursor components, prior to completion of gelation of the soft dielectric casting compound,
d) inserting the soft dielectric casting compound, with ferroelectric particles dispersed therein, into the housing enclosure through the inlet port prior to completion of gelation of the filled soft casting compound, with ferroelectric particles dispersed therein, to form the insulating composition.

13. The method of claim 12 further comprising degassing the soft dielectric casting compound, with ferroelectric particles dispersed therein, prior to completion of its gelation.
